(19) United States
(12) Patent Application Publication
(10) Pub. No.: US 2008/0280392 A1
(43) Pub. Date: Nov. 13, 2008

(54) CONVEX DIE ATTACHMENT METHOD

(76) Inventor: Russell A. Stapleton, Apex, NC (US)

Correspondence Address: LORD CORPORATION;PATENT & LEGAL SERVICES, 111 LORD DRIVE, P.O. Box 8012, CARY, NC, 27512-8012, US

(21) Appl. No.: 12/047,862

(22) Filed: Mar. 13, 2008

Related U.S. Application Data
(60) Provisional application No. 60/894,574, filed on Mar. 13, 2007.

(51) Int. Cl. H01L 21/50

(52) U.S. Cl. 438/106; 264/272.11; 257/E21.499

(57) ABSTRACT

A method for assembling a microelectronic device is provided comprising the step of adhering a die to a substrate using a convex die attachment process. The convex die attachment process generally comprises a) providing a die having an underfill material thereon, b) picking up and inverting the die, c) heating the underfill until it liquefies at least slightly and forms a convex surface, and d) placing the die on a substrate.

### CROSS-REFERENCE TO RELATED APPLICATIONS

The present application claims priority under 35 U.S.C. § 119(e) from U.S. Provisional Patent Application Ser. No. 60/894,574 filed Mar. 13, 2007, entitled “CONVEX DIE ATTACHMENT METHOD”, the disclosure of which is incorporated herein by reference.

### FIELD OF THE INVENTION

The invention relates to electronics packaging. More particularly, the invention relates to a method for assembling an electronic package employing a no-flow underfill applied to the die prior to placing the die on the substrate.

### BACKGROUND OF THE INVENTION

In a traditional fabrication process individual die containing electrical components are constructed in large numbers on a single large “wafer” of semiconductor material, typically silicon. Individual die are provided with small pads of metal that serve as the electrical connections. The individual die are then cut out of the wafer and attached to a housing with small wires leading from the pads. These wires connect to pins on the outside of the housing, which are then attached to a substrate such as a printed circuit board (PCB).

A newer method for chip fabrication call the “flip-chip” process is advantageous because it does not require any wire bonds and is often used for semiconductor devices, such as IC chips. A flip chip is simply a die that is flipped over so the side of the die containing circuitry is nearest the mounting substrate. During the final wafer processing step, solder balls or “bumps” are deposited on the die pads, which are used to connect directly to corresponding connectors engaging circuitry on the substrate.

The processing of a flip chip is similar to conventional IC fabrication with some slight modifications. Once the wafer has been fabricated, a small dot of solder is deposited on each of the pads. The individual die are then cut out of the wafer (diced). The flip chip is attached to a substrate by inverting the chip so the solder balls are positioned downward onto connectors on the underlying electronics or circuit board. The solder is then re-melted (reflowed) to produce an electrical connection between the circuitry on the die and the substrate.

The reflowed solder bumps create a mechanical and electrical connection between the contact areas of the die and the contact areas of the substrate. However, due to the properties of the solder, the mechanical connection is relatively weak and prone to distortion or cracking during natural thermal cycling of the die. Additionally, the underside of the die surface remains exposed, suspended off the surface of the mounting substrate by the flowed solder bumps. An electrically-insulating adhesive, commonly known as an underfill, is typically syringe applied into this space and cured to provide a stronger mechanical connection, provide a thermal bridge, and to ensure the solder joints are not stressed due to differing coefficients of thermal expansion between the die and the substrate.

The underfill flows by capillary action between the die and the substrate, and therefore takes considerable time and application from multiple points to ensure that unfilled voids do not remain between the die and the substrate. Underfill materials are typically epoxy-based and suitably viscous to flow properly yet mechanically strong after setting/curing. Once syringe applied, the underfill is heated to drive out any solvents and/or cure the underfill composition. This may be accomplished prior to or as part of the solder reflow process.

Often, the underfill does not completely fill the space between the components leading to entrapped air under the die. This can lead to catastrophic failure of the part when the heat from the reflow oven causes the entrapped air to expand and burst through the underfill or die.

The manual application of underfill via a syringe is a time consuming and labor intensive step in an otherwise automated process. One attempt to eliminate this step involves coating the substrate in appropriate places with underfill prior to placement of a die on the substrate. This is commonly referred to as a no-flow underfill and is illustrated in FIGS. 1A-1C. Once the wafer has been fabricated, a small dot of solder is deposited on each of the pads. The individual die are then cut out of the wafer (diced). The die 10 comprising solder bumps 20 are then inverted in a position ready to align and place on a substrate, as illustrated in FIG. 1A. FIG. 1B illustrates the die 10 in an inverted position, ready for alignment and placement on the substrate 40, which has been coated with an underfill composition 30. The die 10 is aligned such that the solder bumps 30 are aligned with connectors 50 on the substrate 40. In FIG. 1C, the flip chip 10 is placed and attached to a substrate 40 such that the solder balls 20 are positioned downward onto connectors 50 on the underlying electronics or circuit board 60, and the solder is reflowed. While this process automates the underfill application, there remains an issue with uneven wetting of underfill on the substrate and the solder bumps interfering with air escaping from between the components, which leads to entrapped air 60 between the die and substrate.

### SUMMARY OF THE INVENTION

In a first aspect of the present invention, a method for assembling a microelectronic device is provided comprising the step of adhering a die to a substrate using a convex die attachment process.

In a second aspect of the present invention, a method for forming an electronic assembly is provided comprising:

a) providing a die having an underfill material thereon;

b) picking up and inverting the die;

c) heating the underfill until it liquefies at least slightly and forms a convex surface, and,

d) placing the die on a substrate.

In one embodiment of the present invention, the die comprises microelectronic components. In a further embodiment of the present invention, the die comprises external electrical connections. In a still further embodiment of the present invention, the die comprises solder bumps and in yet another embodiment of the present invention, the underfill material substantially surrounds the solder bumps. In an additional embodiment of the present invention, the substrate comprises solder pads for connecting with the solder bumps.

In a further embodiment of the present invention, the step a) of the method comprises:

a1) providing a wafer;

a2) forming solder bumps on said wafer;

a3) coating said bumped wafer with an underfill material comprising a resin and a solvent;

a4) drying the underfill material to remove substantially all the solvent;

a5) diving the wafer into individual die.

In an additional embodiment of the present invention, the step of drying the underfill material to remove substantially all the solvent is performed under a vacuum and/or the underfill is heated to dry the underfill material.

In one embodiment of the present invention, the step of picking up and inverting the die comprises picking up the die with a heated die bonder which provides the heat for the heating step through the body of the die. In an alternate embodiment of the present invention, the underfill is heated via a hot air stream directed at the die.

In another embodiment of the present invention, the step of positioning and placing the coated die on a substrate comprises:

d1) aligning the solder bumps on the die with corresponding pads on the substrate.

d2) placing the die on the substrate;

d3) allowing the underfill to wet the substrate and substantially fill the space between the die and the substrate;

d4) heating the assembly to solidify the underfill.

In one embodiment of the present invention, the underfill is cured by heating the assembly. In a further embodiment of the present invention, the step of heating the assembly to solidify the underfill comprises heating the substrate to a temperature sufficient to reflow the solder.

In another embodiment of the present invention, the underfill composition comprises an epoxy resin, a solvent, a curative, and optionally a flux. In a further embodiment of the present invention, the curative comprises a thermally latent curative. In yet another embodiment of the present invention, the epoxy resin comprises a solid Bisphenol A or Bisphenol F epoxy resin. In a still further embodiment of the present invention, the melting point of the epoxy resin is less than about 100° C. In an additional embodiment of the present invention, the solvent comprises methylene chloride.

In a still further embodiment of the present invention the substrate comprises another die to form a stacked chip assembly. In an additional embodiment of the present invention, the stacked chip assembly comprises a plurality of die. In another embodiment of the present invention, the substrate is coated with an underfill composition prior to placement of the underfill coated die.

### BRIEF DESCRIPTION OF THE DRAWINGS

FIG. 1 illustrates a microelectronic assembly of the prior art.

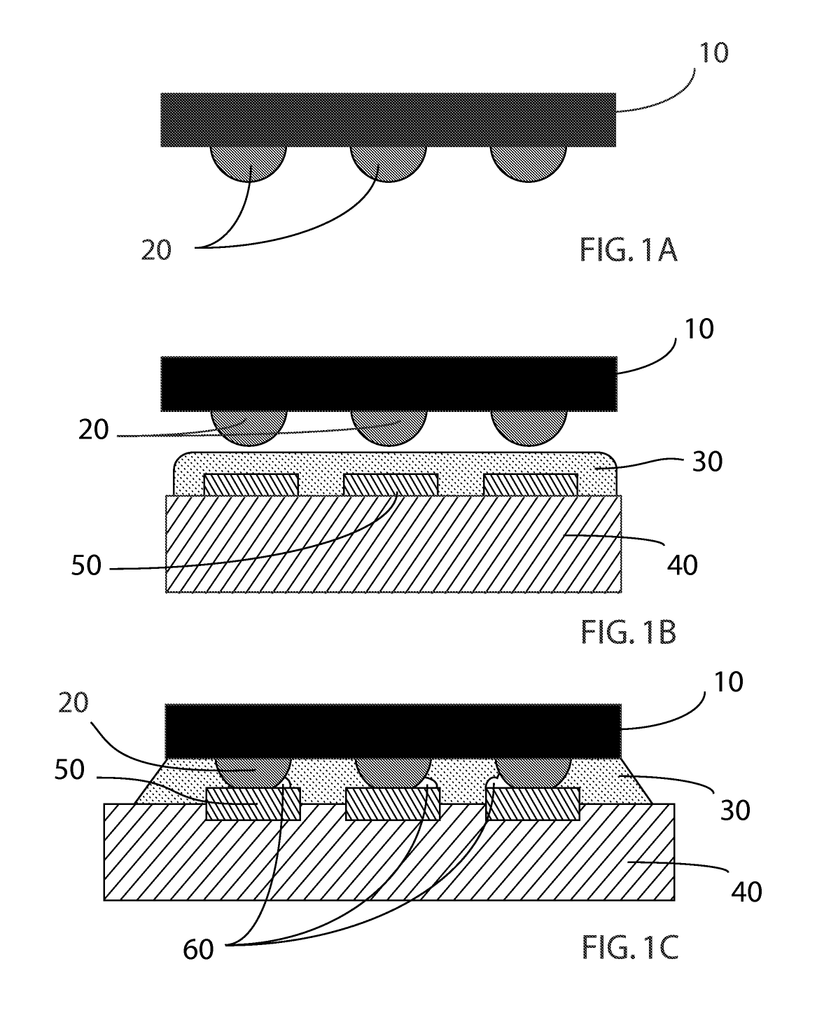

FIG. 2 illustrates the convex die attach process in an embodiment of the present invention including (a) the coated inverted die, (b) the heated die with a convex surface formed thereon, and (c) the placement of the die on the substrate.

FIG. 3 illustrates a complete fabrication and bonding process according to an embodiment of the present invention comprising, (a) the wafer with solder bumps, (b) the wafer with underfill applied, (c) the wafer with dried underfill, (d) the dices wafer, (e) a die picked up and inverted, (f) the die placed on a substrate, and (g) the die adhered to a substrate with the solder reflowed and underfill cured.

### DETAILED DESCRIPTION OF THE INVENTION

In the fabrication of microelectronics there are a variety of methods for manufacturing silicon wafers, adhering solder bumps and dicing the wafers to form individual die. The methods of the various embodiments of the present invention may be easily integrated into existing processes as one skilled in the art will recognize.

In a first aspect of the present invention, a die is coated with an underfill material. The underfill material preferably comprises an epoxy resin. The underfill material may optionally contain one or more of a curative, solvent, flux solution and filler. In one embodiment of the present invention, a wafer comprising a plurality of die is coated, and then diced into individual coated die. In another embodiment of the present invention, a die is coated individually after being cut from a wafer.

In a further embodiment of the present invention, one important characteristic of the underfill composition is its liquefaction temperature. The liquefaction temperature is the temperature at which the solid underfill liquefies and begins to flow, thereby allowing gravity to form a convex surface thereon when the die is inverted. In an embodiment of the present invention, this temperature will lie within the general working and processing ranges for flip chip applications and can vary from about 20° C. to about 270° C. In a preferred embodiment of the present invention, the liquefaction temperature will be within the range of from about 40° C. to about 150° C., and most preferably from about 80° C. to about 120° C.

The underfill composition employed with the method of the present invention may comprise any underfill composition suitable for the heating/liquefaction step as described herein. The underfill composition is tuned to have appropriate viscosity, liquefaction temperature, and any other properties which may be desired for a particular application. In a preferred embodiment of the present invention, the underfill composition comprises an epoxy resin based underfill comprising a thermally latent curative. The thermally latent curative allows the underfill to be heated on the die without initiating the cure so as to allow the underfill to remain uncured throughout the picking/heating/placing steps. Once the die is placed on a substrate, then the underfill is heated above an initiation temperature of the curative to begin cutting the resin. Curing begins when the resin polymerizes or crosslinks to such an extent that the viscosity increases substantially.

In a most preferred embodiment of the present invention, the underfill composition comprises a bisphenol-A or bisphenol-F solid epoxy resin with a melting temperature of below about 100° C., and a thermally latent curative, such as the curative described in U.S. Patent Application Publication No. 2008/0012124 top Stapleton, having a cure initiation temperature of above about 150° C.

In most flip chip devices, the size of the solder balls ranges from 25 μm to 500 μm. Depending upon the application, the underfill may completely cover the solder balls or only cover a portion thereof. Therefore, in an embodiment of the present invention, the thickness of the underfill can vary from 0.1 μm to 10 mm, preferably between 25 μm and 1 mm, and ideally between 100 μm and 400 μm. However, it is recognized that the geometry of the microelectronic assembly and properties of the underfill will dictate the final thickness as applied.

In an embodiment of the present invention wherein the underfill material comprises a solvent, a drying step is necessary to remove the solvent from the underfill material prior to placement. The drying step comprises, for example, heating the underfill to evaporate the solvent or placing the underfill material under a vacuum to remove the solvent from the underfill material.

Once the die is coated with underfill material and any solvent driven off, the coated die can optionally be stored for a period of time until the microelectronic assembly is to be constructed.

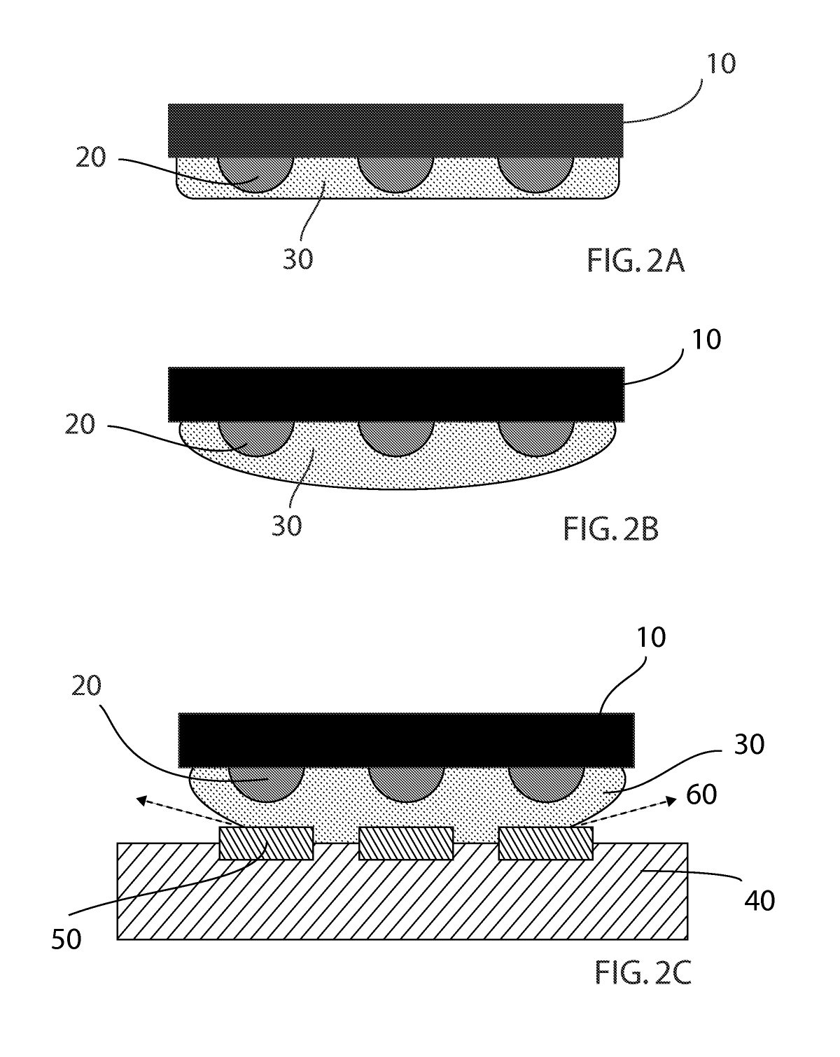

In a further embodiment of the present invention, illustrated in FIGS. 2A-2C, the underfill 30 coated die 10 is picked up and inverted such that the solder balls 20 and underfill composition 30 are oriented downward. The underfill 20 coated die 10 are then heated. Upon heating to a sufficient temperature, at or near the liquefaction temperature of the underfill, gravitational forces and surface tension will cause the underfill to form a convex surface, as is illustrated in FIG. 2B. In embodiments of the present invention, the shape of the convex surface can be tuned using temperature, coating thickness, viscosity, and surface energy of the underfill. The heated die 10 comprising an underfill composition 30 having a convex surface, is then positioned and placed on a substrate 40. The convex shape of the underfill 30 allows air to escape 60 so as to prevent air entrapment between the die 10 and the substrate 40.

In an embodiment of the present invention, the picking, heating, and placing of the die is facilitated through a heated die bonder. Die bonders generally employ a placement head which picks up the die via suction, aligns the board and the die for placement, then places the die on the board and stops the suction to release the die. A heated die bonder, such as those sold by Datacon (Datacon North America, Trevose, Pa. 19053), simultaneously allows heating of the die and/or substrate while the die is being placed. Means for heating the die include heating the placement head to heat the die through conduction, heating the substrate via heat conducted from the die bonder or convective heating of the board and/or substrate via a hot air stream.

The die is placed such that the solder balls contact corresponding connector pads on the substrate to allow electrical interconnections between the die and the substrate, preferably a printed circuit board. The convex shape of the underfill allows space for air to escape as the underfill wets the substrate. This prevents the entrapment of air which is undesirable as discussed herein. The underfill material is allowed to wet the surface of the substrate and substantially fill the area between the die and the substrate, surrounding the solder balls. In a preferred embodiment of the present invention, the substrate completely surrounds the solder balls leaving no void spaces in the underfill.

In an alternate embodiment of the present invention, the pick and place step is performed using a tilted or uneven pick and place head. This would allow placement of the die where the apex of the convex coating is off center relative to the die. Similarly, in certain situations it may be advantageous to hold the substrate at an angle relative to the die so as to provide the same off-center alignment.

In a further embodiment of the present invention, both the die and the substrate are heated during the placement step. Heating the die and the board ensures that the underfill remains liquid until it has an opportunity to adequately wet the surface of the substrate. Generally, the temperatures will be within a normal operating range of between about 20° C. and about 270° C. In a preferred embodiment of the present invention, the temperature will be between about 40° C. and about 150° C., and ideally between about 80° C. and about 120° C.

Once the die is placed on the substrate, the microelectronic assembly is heated to reflow the solder and cure the underfill composition. In an alternate embodiment of the present invention the underfill is cooled after placement but prior to reflowing the solder. This allows the underfill composition to re-solidify and hold the assembly together. This can be advantageous when there is a time lag between placement and reflow, or where the assembly must be moved or stored between these steps. In an additional embodiment of the present invention, the assembly is subjected to a post-bake process to cure the underfill at a temperature less than the reflow temperature of the solder.

In a further embodiment of the present invention, the substrate is coated with an underfill material as well as the die. A coating of underfill on the substrate provides an even contact surface by covering any surface features of the substrate such as solder masks or protruding electrical interconnects. The underfill employed on the substrate may differ in formulation that that coating the die. However, in a preferred embodiment of the present invention, the underfill composition on the substrate is substantially identical to the underfill composition on the die. Additionally, coating the substrate provides an underfill to underfill contact when the die is placed which improves wetting and further reduces the possibility of entrapped air during the placement process.

In another embodiment of the present invention, the substrate comprises another die. In this embodiment, the microelectronic assembly is constructed by stacking die, one on top of another with electrical interconnections therebetween. It is within the scope of this embodiment of the present invention to provide a plurality of stacked die in an assembly, prepared according to the methods of the various embodiments herein.

### EXAMPLE

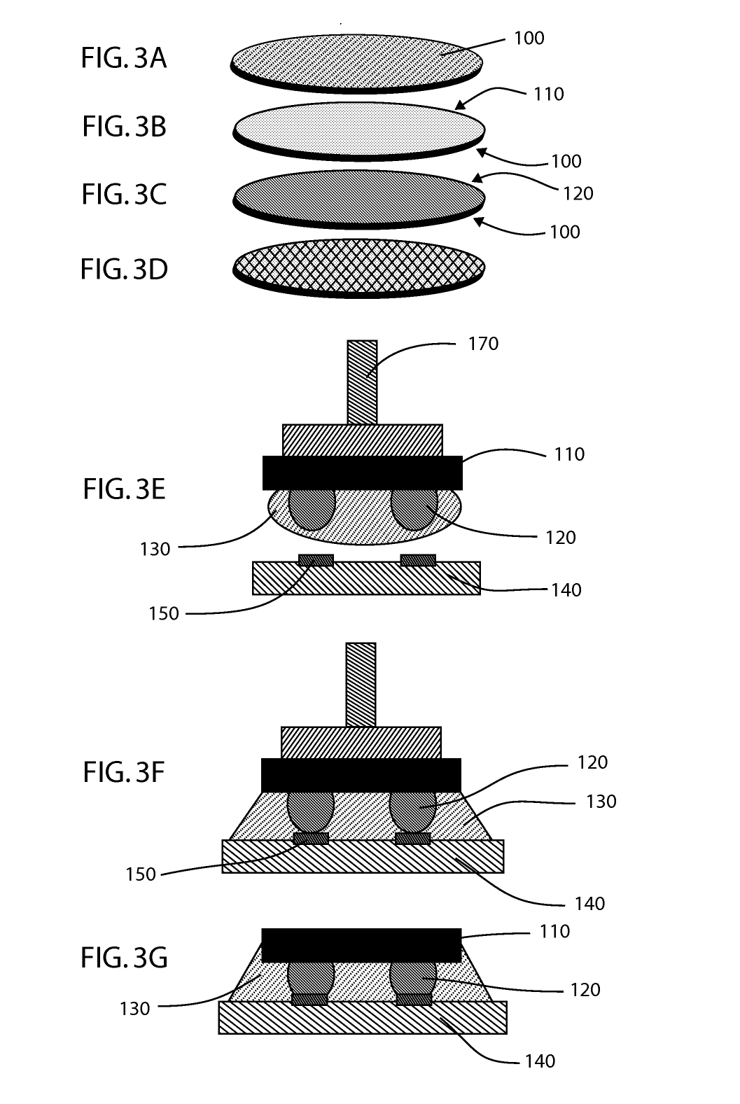

In a first exemplary embodiment of the present invention, illustrated in FIGS. 3A-3G, the method of an embodiment of the present invention was incorporated into a microelectronic manufacturing process. In FIG. 3A the process begins with a wafer 100 having a plurality of solder bumps 120 formed thereon. In FIG. 3B the wafer 100 is coated with an underfill material 130, which completely covers the solder bumps 120. The underfill 130 comprises a solid epoxy, thermally latent curative, solvent, and flux solution according to Table 1.

TABLE 1
Underfill Composition

| Weight | Weight Percent | | |
|---|---|---|---|
| Percent Total | Solids | Trade Name | Function |
| 80 | 80 | EPON 1002 | Epoxy |
| | 17 | Diacid 1400 | Flux |
| | 3 | LORD Curative* | Latent Curative |
| 20 | | Methylene Chloride | Solvent |

*LORD Curative comprises a curative as described in U.S. Patent Application Publication No. 2008/0012124 to Stapleton.

The underfill composition 130 is then hardened as shown in FIG. 3C by removing the coating solvent with heat and slight vacuum to yield a non-tacky dry coating on the die 100, which completely covered the solder bumps 120. The wafer 100 is then diced by cutting individual dies 110, as shown in FIG. 3D.

As shown in FIG. 3E, an individual die 110 are then picked up using a heated die bonder 170, at which time the solid uncured resin 130 liquefied to yield a convex surface. In FIG. 3F, the die 110 with the low viscosity convex surface is then aligned and placed onto a heated board 140, allowing the resin 130 to wet the surface of the board 140 during the attachment process. The board 140 is simultaneously heated to a temperature below that which would damage the board 140 or initiate solidification of the resin during placement.

The die 110 and board 140 are then run through a reflow oven to form a physical connection between the 120 and the electrical components 150 on the board 140. The assembly was then post baked at 180-200° C. for 1 hour to ensure the underfill composition is fully cured.

Although the present invention has been described with reference to particular embodiments, it should be recognized that these embodiments are merely illustrative of the principles of the present invention. Those of ordinary skill in the art will appreciate that the apparatus and methods of the present invention may be constructed and implemented in other ways and embodiments. Accordingly, the description herein should not be read as limiting the present invention, as other embodiments also fall within the scope of the present invention.

Although the present invention has been described with reference to particular embodiments, it should be recognized that these embodiments are merely illustrative of the principles of the present invention. Those of ordinary skill in the art will appreciate that the compositions, apparatus and methods of the present invention may be constructed and implemented in other ways and embodiments. Accordingly, the description herein should not be read as limiting the present invention, as other embodiments also fall within the scope of the present invention as defined by the appended claims.

What is claimed is:

1. A method for forming an electronic assembly comprising:
a) providing a die having an underfill material thereon;
b) picking up and inverting the die;
c) heating the underfill until it liquefies at least slightly and forms a convex surface, and,
d) placing the die on a substrate.

2. The process of claim 1, wherein the die comprises microelectronic components.

3. The process of claim 1, wherein the die comprises external electrical connections.

4. The process of claim 1, wherein the die comprises solder bumps.

5. The process of claim 4, wherein in step a) the underfill material substantially surrounds the solder bumps.

6. The process of claim 1, wherein the substrate comprises solder pads for connecting with the solder bumps.

7. The process of claim 1, wherein step a) comprises:
a 1) providing a wafer;
a2) forming solder bumps on said wafer;
a3) coating said bumped wafer with an underfill material comprising a resin and a solvent;
a4) drying the underfill material to remove substantially all the solvent;
a5) diving the wafer into individual die.

8. The process of claim 7, wherein step a4) is performed under a vacuum.

9. The process of claim 7, wherein in step a4) the underfill is heated to dry the underfill material.

10. The process of claim 1, wherein step b) comprises picking up the die with a heated die bonder which provides the heat for step c) through the body of the die.

11. The process of claim 1, wherein in step c) the underfill is heated via a hot air stream directed at the die.

12. The process of claim 1, wherein step d) comprises:
d1) aligning the solder bumps on the die with corresponding pads on the substrate.
d2) placing the die on the substrate;
d3) allowing the underfill to wet the substrate and substantially fill the space between the die and the substrate;
d4) heating the assembly to solidify the underfill.

13. The process of step 12, wherein in step d4) the underfill is cured.

14. The process of claim 12, wherein step d4) comprises heating the substrate to a temperature sufficient to reflow the solder.

15. The process of claim 1, wherein the underfill composition comprises an epoxy resin, a solvent, a curative, and optionally a flux.

16. The process of claim 15, wherein the curative comprises a thermally latent curative.

17. The process of claim 16, wherein the epoxy resin comprises a solid Bisphenol A or Bisphenol F epoxy resin.

18. The process of claim 16, wherein the melting point of the epoxy resin is less than about 100° C.

19. The process of claim 15, wherein the solvent comprises methylene chloride.

20. The process of claim 1, wherein the substrate comprises another die to form a stacked chip assembly.

21. The process of claim 20, wherein the stacked chip assembly comprises a plurality of die.

22. The process of claim 1, wherein the substrate is coated with an underfill composition prior to placement of the underfill coated die.
